(19) United States
(12) Patent Application Publication
(10) Pub. No.: US 2010/0283139 A1
(43) Pub. Date: Nov. 11, 2010

(54) Semiconductor Device Package Having Chip With Conductive Layer

(76) Inventors: Hung-Hsiang CHENG, Kaohsiung (TW); Chih-Yi HUANG, Kaohsiung (TW)

Correspondence Address: MCCRACKEN & FRANK LLP, 311 S. WACKER DRIVE, SUITE 2500, CHICAGO, IL, 60606, US

(21) Appl. No.: 12/706,394

(22) Filed: Feb. 16, 2010

(30) Foreign Application Priority Data
May 8, 2009 (TW) 098115446

(51) Int. Cl. H01L 23/498

(52) U.S. Cl. 257/680; 257/690; 257/E23.06

(57) ABSTRACT

The present invention relates to a semiconductor device package having a chip with a conductive layer. The semiconductor device package includes a substrate, a chip, at least one first electrical connecting element and at least one second electrical connecting element. The substrate has a first surface and a first circuit layer. The first circuit layer is disposed adjacent to the first surface. The chip is attached to the substrate and has a surface, at least one first pad, a plurality of second pads and a conductive layer. The first pad, the second pads and the conductive layer are disposed adjacent to the surface, and the conductive layer connects the second pads.

The first electrical connecting element and the second electrical connecting element electrically connect the substrate to the chip. Therefore, the conductive layer of the chip has the effects of controlling the characteristic impedance and increasing the signal integrity.

### BACKGROUND OF THE INVENTION

1. Field of the Invention

The present invention relates to a semiconductor device package, and more particularly to a semiconductor device package having a chip with a conductive layer.

2. Description of the Related Art

FIG. 1 shows a cross-sectional view of a conventional semiconductor device package. The semiconductor device package 1 comprises a substrate 11, a chip 12, at least one first electrical connecting element 13, at least one second electrical connecting element 14, a molding compound 15 and a plurality of solder balls 16. The substrate 11 has a first surface 111, a first circuit layer 112 and a window 113. The first circuit layer 112 is disposed on the first surface 111 and comprises a plurality of first fingers 1121, a plurality of second fingers 1124, a plurality of input/output pads 1122 and a conductive trace 1123. The conductive trace 1123 connects the first fingers 1121, the second fingers 1124 and the input/output pads 1122. The chip 12 is attached to the substrate 11 and has a surface 121, at least one first pad 122 and a plurality of second pads 123. The first pads 122 and the second pads 123 are disposed on the surface 121, and the window 113 of the substrate 11 exposes the first pads 122 and the second pads 123 of the chip 12. The first electrical connecting elements 13 electrically connect the first fingers 1121 of the first circuit layer 112 of the substrate 11 to the first pads 122 of the chip 12. The second electrical connecting elements 14 electrically connect the second fingers 1124 of the first circuit layer 112 of the substrate 11 to the second pads 123 of the chip 12. The molding compound 15 encapsulates the substrate 11, the chip 12, the first electrical connecting elements 13 and the second electrical connecting elements 14.

The conventional semiconductor device package 1 has the following disadvantages. The substrate 11 is a single-layered plate, and therefore when a signal is transmitted by the substrate 11 to the chip 12, the substrate 11 lacks a power/ground plane as a reference plane for controlling the impedance of the signal, which causes higher impedance and bad influence to electrical property.

Therefore, it is necessary to provide a semiconductor device package having a chip with a conductive layer to solve the above problems.

### SUMMARY OF THE INVENTION

The present invention is directed to a semiconductor device package having a chip with a conductive layer. The semiconductor device package comprises a substrate, a chip, at least one first electrical connecting element and at least one second electrical connecting element. The substrate has a first surface and a first circuit layer. The first circuit layer is disposed adjacent to the first surface. The chip is attached to the substrate and has a surface, at least one first pad, a plurality of second pads and a conductive layer. The first pad, the second pads and the conductive layer are disposed adjacent to the surface, and the conductive layer connects the second pads. The first electrical connecting element electrically connects the first circuit layer of the substrate to the first pad of the chip. The second electrical connecting element electrically connects the first circuit layer of the substrate to the conductive layer of the chip.

Whereby, the conductive layer of the chip has the effects of controlling the characteristic impedance and increasing the signal integrity.

### BRIEF DESCRIPTION OF THE DRAWINGS

FIG. 1 is a cross-sectional view of a conventional semiconductor device package;

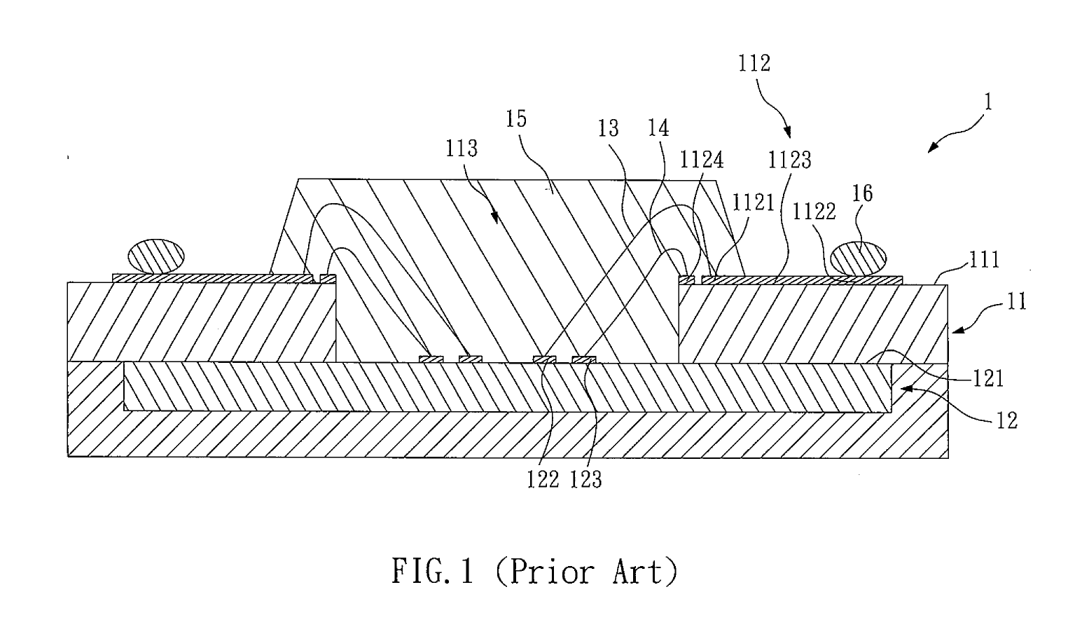

FIG. 2 is a cross-sectional view of a semiconductor device package having a chip with a conductive layer according to a first embodiment of the present invention;

FIG. 3 is a top view of the chip of the semiconductor device package in FIG. 2, wherein a chip passivation is omitted;

FIG. 4 is a cross-sectional view of a semiconductor device package having a chip with a conductive layer according to a second embodiment of the present invention;

FIG. 5 is a cross-sectional view of a semiconductor device package having a chip with a conductive layer according to a third embodiment of the present invention;

FIG. 6 is a cross-sectional view of a semiconductor device package having a chip with a conductive layer according to a fourth embodiment of the present invention; and

FIG. 7 is a cross-sectional view of a semiconductor device package having a chip with a conductive layer according to a fifth embodiment of the present invention.

### DETAILED DESCRIPTION

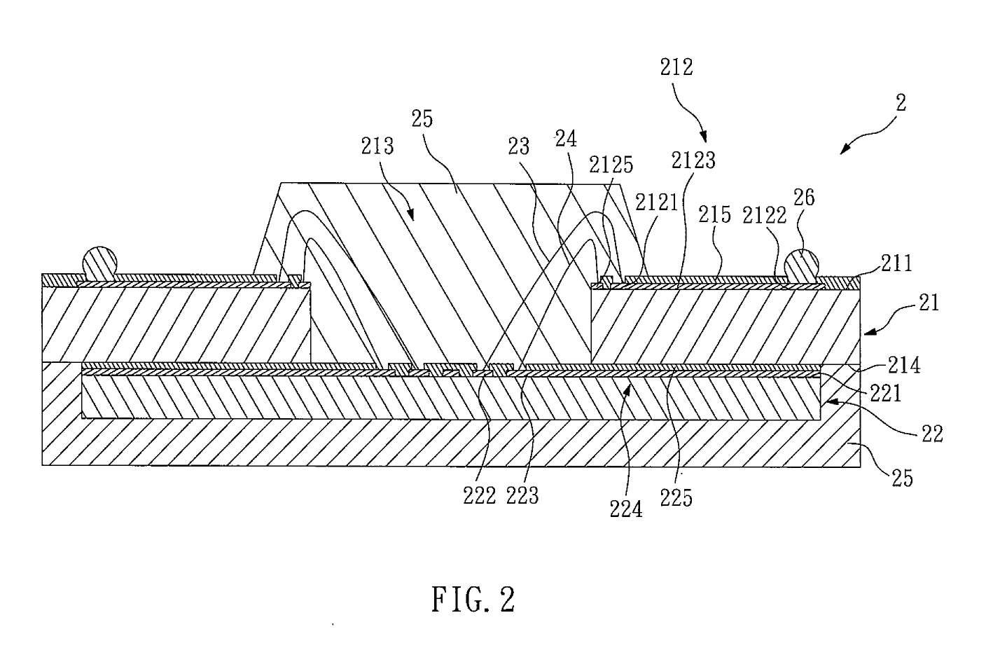

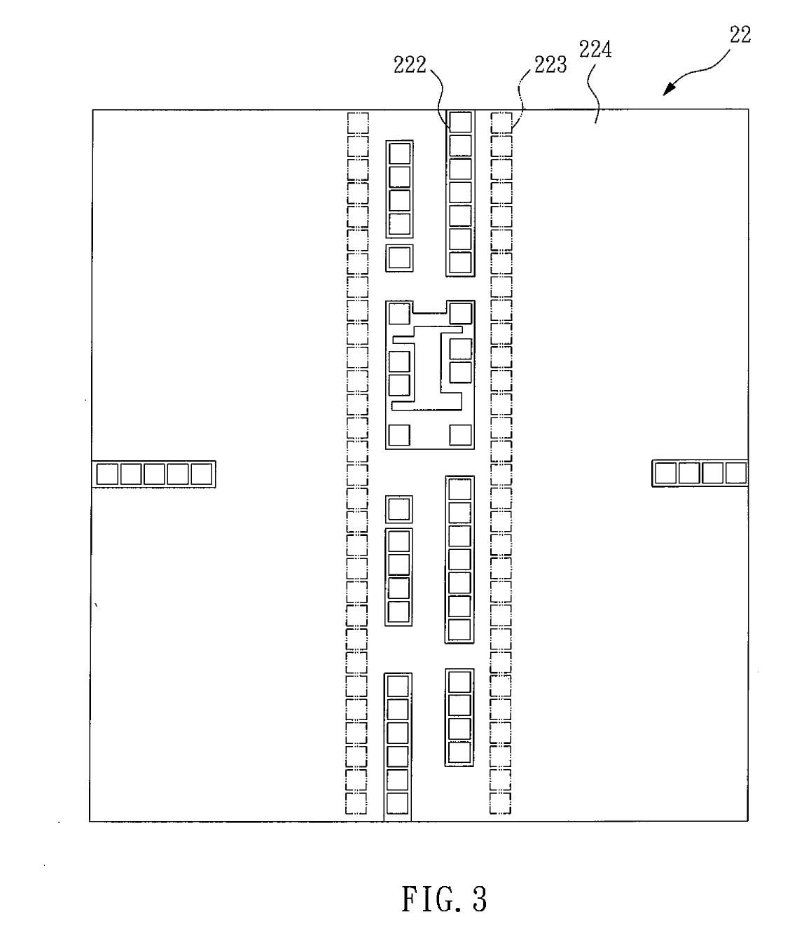

FIG. 2 shows a cross-sectional view of a semiconductor device package having a chip with a conductive layer according to a first embodiment of the present invention. FIG. 3 shows a top view of the chip of the semiconductor device package in FIG. 2, wherein a chip passivation is omitted. The semiconductor device package 2 comprises a substrate 21, a chip 22, at least one first electrical connecting element (for example, a plurality of first wires 23) and at least one second electrical connecting element (for example, a plurality of second wires 24). The substrate 21 has a first surface 211, a first circuit layer 212, a window 213, a second surface 214 and a first substrate passivation 215. The first circuit layer 212 is disposed adjacent to the first surface 211. In the embodiment, the first circuit layer 212 comprises a plurality of first fingers 2121, a plurality of second fingers 2125, a plurality of input/output pads 2122 and a conductive trace 2123. The conductive trace 2123 connects the first fingers 2121, the second fingers 2125 and the input/output pads 2122. The first substrate passivation 215 is disposed adjacent to the first circuit layer 212 and exposes the first fingers 2121, the second fingers 2125 and the input/output pads 2122. The substrate 21 is a single-layered plate.

The chip 22 is attached to the substrate 21 and has a surface 221, at least one first pad 222, a plurality of second pads 223 and a conductive layer 224. The first pad 222, the second pads 223 and the conductive layer 224 are disposed adjacent to the surface 221. The first pad 222 is used to transmit input/output signals. The second pads 223 are used to ground or power. The conductive layer 224 connects the second pads 223. The conductive layer 224 is a plane having a large area, and the area of the conductive layer 224 covers the second pads 223. In the embodiment, the chip 22 is a wire-bonded chip. The window 213 of the substrate 21 exposes the first pads 222 and the second pads 223 of the chip 22, and the surface 221 of the chip 22 is attached to the second surface 214 of the substrate 21. Therefore, a window ball grid array package is formed. The conductive layer 224 of the chip 22 is a power/ground plane. The chip 22 further comprises a chip passivation 225. The chip passivation 225 is disposed adjacent to the conductive layer 224, and exposes the first pads 222 and part of the conductive layer 224.

The first electrical connecting elements electrically connect the first circuit layer 212 of the substrate 21 to the first pads 222 of the chip 22. The second electrical connecting elements electrically connect the first circuit layer 212 of the substrate 21 to the conductive layer 224 of the chip 22. In the embodiment, the first electrical connecting elements are a plurality of first wires 23 which electrically connect the first fingers 2121 of the first circuit layer 212 of the substrate 21 to the first pads 222 of the chip 22, the second electrical connecting elements are a plurality of second wires 24 which electrically connect the second fingers 2125 of the first circuit layer 212 of the substrate 21 to the second pads 223 of the chip 22. In the embodiment, the semiconductor device package 2 further comprises a molding compound 25 and a plurality of input/output solder balls 26. The molding compound 25 encapsulates the substrate 21, the chip 22, the first electrical connecting elements and the second electrical connecting elements. The input/output solder balls 26 are disposed adjacent to the input/output pads 2122 of the first circuit layer 212 of the substrate 21.

To a high-speed signal, a reference plane is very important for controlling the characteristic impedance and increasing the signal integrity. In the present invention, the conductive layer 224 of the chip 22 is a reference plane when transmitting the high-speed signal on the substrate 21. Therefore, the conductive layer 224 of the chip 22 has the effects of controlling the characteristic impedance and increasing the signal integrity.

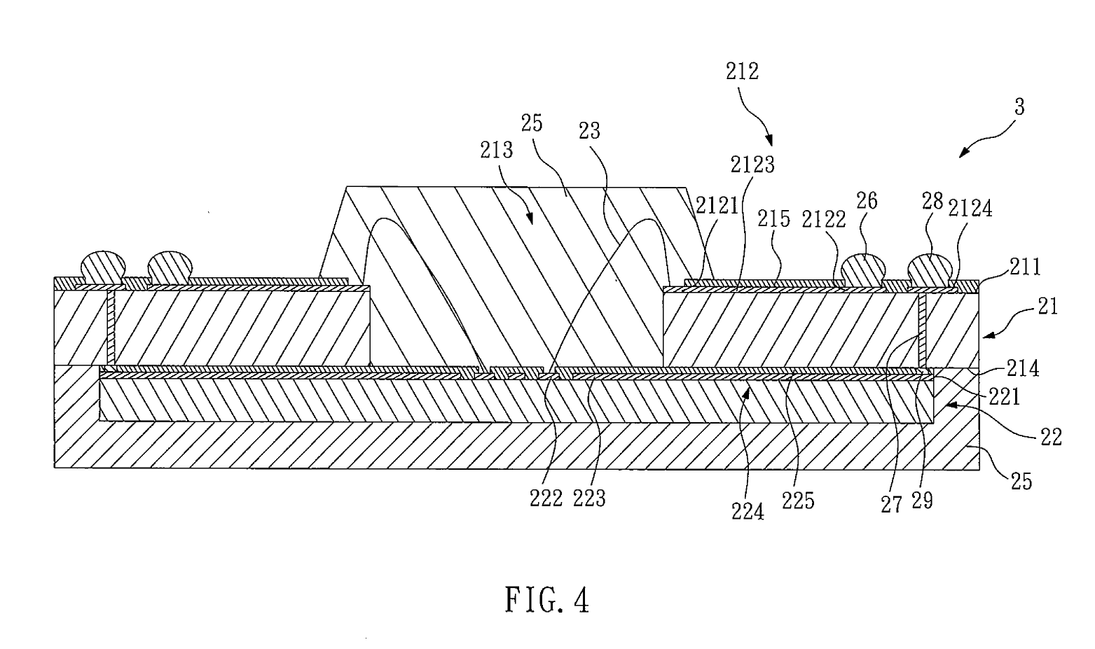

FIG. 4 shows a cross-sectional view of a semiconductor device package having a chip with a conductive layer according to a second embodiment of the present invention. The semiconductor device package 3 according to the second embodiment is substantially the same as the s semiconductor device package 2 (FIG. 2) according to the first embodiment, and the same elements are designated by the same reference numbers. In the embodiment, the first circuit layer 212 of the substrate 21 further comprises a plurality of power/ground pads 2124. The second electrical connecting elements are a plurality of first through vias 27 which penetrate through the substrate 21. The semiconductor device package 3 further comprises a plurality of power/ground solder balls 28 and a plurality of first bumps 29. The power/ground solder balls 28 are disposed adjacent to the power/ground pads 2124 of the first circuit layer 212 of the substrate 21. The first bumps 29 electrically connect the first through vias 27 to the conductive layer 224 of the chip 22.

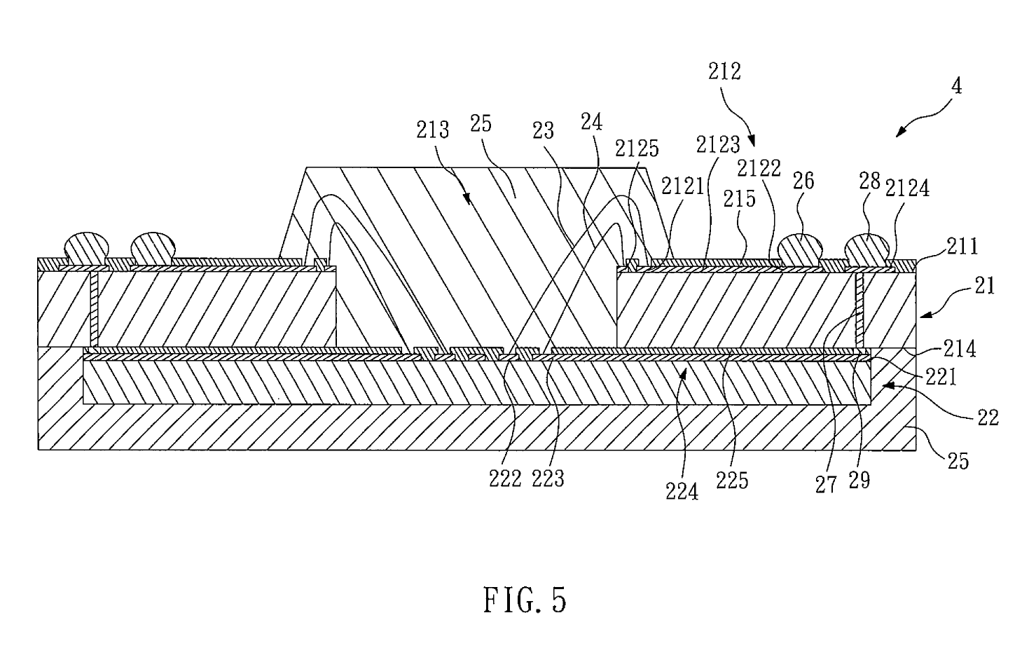

FIG. 5 shows a cross-sectional view of a semiconductor device package having a chip with a conductive layer according to a third embodiment of the present invention. The semiconductor device package 4 according to the third embodiment is substantially the same as the semiconductor device package 3 (FIG. 4) according to the second embodiment, and the same elements are designated by the same reference numbers. The semiconductor device package 4 according to the third embodiment is different from the semiconductor device package 3 according to the second embodiment in the amount and the form of the second electrical connecting elements. In the embodiment, the semiconductor device package 4 comprises four second electrical connecting elements, wherein two of the second electrical connecting elements are the second wires 24, and the other two second electrical connecting elements are the first through vias 27.

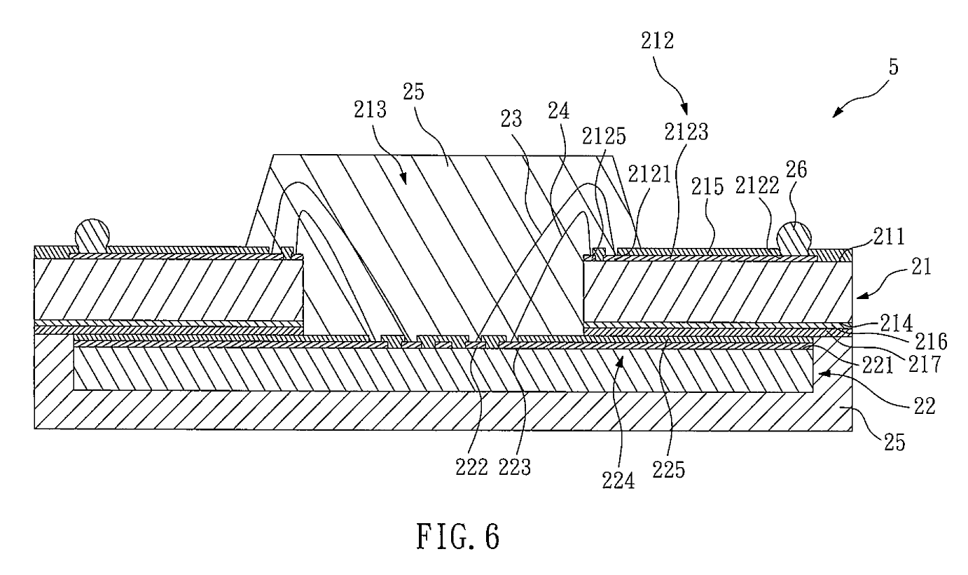

FIG. 6 shows a cross-sectional view of a semiconductor device package having a chip with a conductive layer according to a fourth embodiment of the present invention. The semiconductor device package 5 according to the fourth embodiment is substantially the same as the semiconductor device package 2 (FIG. 2) according to the first embodiment, and the same elements are designated by the same reference numbers. The semiconductor device package 5 according to the fourth embodiment is different from the semiconductor device package 2 according to the first embodiment in the form of the substrate 21. In the embodiment, the substrate 21 is a double-layered plate. The substrate 21 further comprises a second circuit layer 216 and a second substrate passivation 217. The second circuit layer 216 is a power/ground plane, and is disposed adjacent to the second surface 214. The second substrate passivation 217 is disposed adjacent to the second circuit layer 216.

Therefore, the conductive layer 224 of the chip 22 has strong coupling with the second circuit layer 216 of the substrate 21, which facilitates suppressing the noise of the power/ground plane.

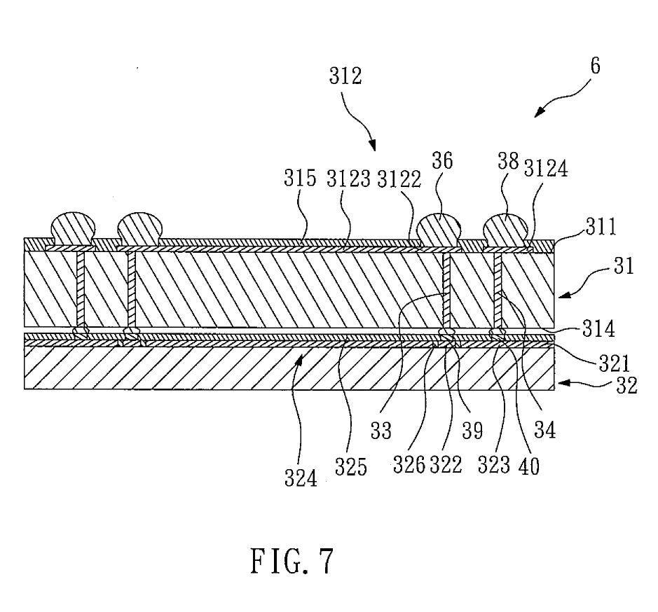

FIG. 7 shows a cross-sectional view of a semiconductor device package having a chip with a conductive layer according to a fifth embodiment of the present invention. The semiconductor device package 6 comprises a substrate 31, a chip 32, at least one first electrical connecting element (for example, a plurality of second through vias 33) and at least one second electrical connecting element (for example, a plurality of third through vias 34). The substrate 31 has a first surface 311, a first circuit layer 312, a second surface 314 and a first substrate passivation 315. The first circuit layer 312 is disposed adjacent to the first surface 311. In the embodiment, the first circuit layer 312 comprises a plurality of input/output pads 3122, a conductive trace 3123 and a plurality of power/ground pads 3124. The conductive trace 3123 connects the input/output pads 3122. The first substrate passivation 315 is disposed adjacent to the first circuit layer 312, and exposes the input/output pads 3122 and the power/ground pads 3124. The substrate 31 is a single-layered plate.

The chip 32 is attached to the substrate 31 and has a surface 321, at least one first pad 322, a plurality of second pads 323 and a conductive layer 324. The first pad 322, the second pads 323 and the conductive layer 324 are disposed adjacent to the surface 321. The first pad 322 is used to transmit input/output signals. The second pads 323 are used to ground or power. The conductive layer 324 connects the second pads 323. The conductive layer 324 is a plane having a large area, and the area of the conductive layer 324 covers the second pads 323. In the embodiment, the chip 32 is a flip chip. The conductive layer 324 of the chip 32 is a power/ground plane. The chip 32 further comprises a chip passivation 325 and an insulating material 326. The chip passivation 325 is disposed adjacent to the conductive layer 324, and exposes the first pads 322 and part of the conductive layer 324. The insulating material 326 is used to electrically insulate the first pads 322 and the conductive layer 324.

The first electrical connecting elements electrically connect the first circuit layer 312 of the substrate 31 to the first pads 322 of the chip 32. The second electrical connecting elements electrically connect the first circuit layer 312 of the substrate 31 to the conductive layer 324 of the chip 32. In the embodiment, the first electrical connecting elements are a plurality of second through vias 33 which electrically connect the input/output pads 3122 of the first circuit layer 312 of the substrate 31 to the first pads 322 of the chip 32, the second electrical connecting elements are a plurality of third through vias 34 which electrically connect the power/ground pads 3124 of the first circuit layer 312 of the substrate 31 to the second pads 323 of the chip 32.

In the embodiment, the semiconductor device package 6 further comprises a plurality of input/output solder balls 36, a plurality of power/ground solder balls 38, a plurality of second bumps 39 and a plurality of third bumps 40. The input/output solder balls 36 are disposed adjacent to the input/output pads 3122 of the first circuit layer 312 of the substrate 31. The power/ground solder balls 38 are disposed adjacent to the power/ground pads 3124 of the first circuit layer 312 of the substrate 31. The second bumps 39 electrically connect the second through vias 33 to the first pads 322 of the chip 32. The third bumps 40 electrically connect the third through vias 34 to the conductive layer 324 of the chip 32. However, in other applications, the semiconductor device package 6 may further comprises an underfill covering the second bumps 39 and the third bumps 40.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms illustrated, and that all modifications which maintain the spirit and scope of the present invention are within the scope defined by the appended claims.

What is claimed is:

1. A semiconductor device package having a chip with a conductive layer, comprising:
a substrate, having a first surface and a first circuit layer, wherein the first circuit layer is disposed adjacent to the first surface;
a chip, attached to the substrate and having a surface, at least one first pad, a plurality of second pads and a conductive layer, wherein the first pad, the second pads and the conductive layer are disposed adjacent to the surface, and the conductive layer connects the second pads;
at least one first electrical connecting element, electrically connecting the first circuit layer of the substrate to the first pad of the chip; and
at least one second electrical connecting element, electrically connecting the first circuit layer of the substrate to the conductive layer of the chip.

2. The package as claimed in claim 1, wherein the substrate further has a window and a second surface, the window exposes the first pad and the second pads of the chip, and the surface of the chip is attached to the second surface of the substrate.

3. The package as claimed in claim 1, wherein the substrate is a single-layered plate.

4. The package as claimed in claim 1, wherein the substrate is a multi-layered plate.

5. The package as claimed in claim 1, wherein the first pad of the chip is used to transmit input/output signals.

6. The package as claimed in claim 1, wherein the conductive layer of the chip is a power/ground plane.

7. The package as claimed in claim 1, wherein the chip further comprises a chip passivation disposed adjacent to the conductive layer.

8. The package as claimed in claim 1, further comprising a molding compound encapsulating the substrate, the chip, the first electrical connecting element and the second electrical connecting element, wherein the chip is a wire-bonded chip.

9. The package as claimed in claim 8, wherein the first circuit layer comprises a plurality of first fingers, the first electrical connecting element are a plurality of first wires which electrically connect the first fingers of the first circuit layer of the substrate to the first pad of the chip.

10. The package as claimed in claim 8, wherein the first circuit layer comprises a plurality of second fingers, the second electrical connecting element are a plurality of second wires which electrically connect the second fingers of the first circuit layer of the substrate to the second pads of the chip.

11. The package as claimed in claim 8, wherein the second electrical connecting element is a through via which penetrates through the substrate.

12. The package as claimed in claim 1, wherein the chip is a flip chip.

13. The package as claimed in claim 12, wherein the first electrical connecting element is a through via which penetrates through the substrate.

14. The package as claimed in claim 12, wherein the second electrical connecting element is a through via which penetrates through the substrate.

15. The package as claimed in claim 1, wherein the conductive layer is a plane having a large area, and the area of the conductive layer covers the second pads.

16. The package as claimed in claim 1, further comprising a plurality of input/output solder balls, wherein the first circuit layer comprises a plurality of input/output pads disposed adjacent to the input/output pads.

17. The package as claimed in claim 1, further comprising a plurality of power/ground solder balls, wherein the first circuit layer comprises a plurality of power/ground pads, the power/ground solder balls are disposed adjacent to the power/ground pads.
